(19) United States
(12) Patent Application Publication
(10) Pub. No.: US 2026/0081513 A1
(43) Pub. Date: Mar. 19, 2026

(54) CURRENT SENSING CIRCUIT

(71) Applicant: STMicroelectronics International N.V., Geneva (CH)

(72) Inventor: Bruno LECONTE, Rousset (FR)

(73) Assignee: STMicroelectronics International N.V., Geneva (CH)

(21) Appl. No.: 19/317,600

(22) Filed: Sep. 3, 2025

(30) Foreign Application Priority Data
Sep. 13, 2024 (FR) FR2409737

(51) Int. Cl. H02M 1/00; G01R 19/15; G01R 19/165

(52) U.S. Cl. CPC H02M 1/0009; G01R 19/15; G01R 19/16519; G01R 19/16528; G01R 19/16538

(57) ABSTRACT

A circuit senses a first output current of a switched-mode power supply. The circuit includes a sample-and-hold assembly configured to store an image of said first output current during a non-conduction phase of a high-voltage switch of the switched-mode power supply.

### PRIORITY CLAIM

This application claims the priority benefit of French Application for Patent No. FR2409737, filed on Sep. 13, 2024, the content of which is hereby incorporated by reference in its entirety to the maximum extent allowable by law.

### TECHNICAL FIELD

The present disclosure generally concerns electronic systems and circuits and, in particular, electronic systems and circuits configured to deliver a power supply. The present disclosure more specifically concerns a switched-mode power supply and a circuit enabling to deliver an image of an output current of a switched-mode power supply.

### BACKGROUND

There exist several types of power supply circuits, enabling to deliver a current/voltage pair to an electronic circuit, or device, or system, or more generally to a load. Linear power supplies and switched-mode power supplies are examples of power supply circuits.

A switched-mode power supply is a power supply circuit configured to deliver a DC voltage from an input voltage. Switched-mode power supplies are generally DC/DC converters, taking a DC voltage as input, but some switched-mode power supplies may comprise a rectifying stage enabling them to take as an input an AC voltage, for example the mains.

A switched-mode power supply is often equipped with one or a plurality of circuits enabling to measure the current and/or the voltage that it delivers. These circuits have, for example, the purpose of checking the proper operation of the switched-mode power supply.

It would be desirable to be able to improve, at least partly, certain aspects of known switched-mode power supplies, and, in particular, certain aspects of circuits for sensing the current of switched-mode power supplies.

There exists a need for higher-performance switched-mode power supplies.

There exists a need for switched-mode power supplies comprising higher-performance current sensing circuits.

There is a need to overcome all or part of the disadvantages of known switched-mode power supplies.

There is a need to overcome all or part of the disadvantages of known circuits for sensing the current of switched-mode power supplies.

### SUMMARY

An embodiment provides a current sensing circuit configured to measure an output current of a switched-mode power supply.

An embodiment provides a current sensing circuit comprising a sampling circuit.

An embodiment provides a circuit for sensing a first output current of a switched-mode power supply comprising a sample-and-hold assembly configured to store an image of said first output current during a non-conduction phase of a high-voltage switch of said switched-mode power supply.

Another embodiment provides a current sensing method using a circuit for sensing a first output current of a switched-mode power supply comprising a sample-and-hold assembly configured to store an image of said first output current during a non-conduction phase of a high-voltage switch of said switched-mode power supply.

According to an embodiment, said image is an image of the current flowing in said high-voltage switch.

According to an embodiment, a result provided by said sample-and-hold assembly is compared to a threshold, in order to provide an information about a threshold exceeding.

According to an embodiment, said threshold is provided by a reference current provided by a digital to analog converter.

According to an embodiment, said sample-and-hold assembly comprises a switch and a capacitor.

According to an embodiment, said sample-and-hold assembly is controlled by a sampling signal.

According to an embodiment, said sampling signal triggers the storage of said image of said first current with a time delay.

According to an embodiment, said sample-and-hold circuit is configured to directly receive said first current.

According to an embodiment, said circuit comprises: a control loop configured to receive a first current to be sensed; and a first transistor and a second transistor connected as a current mirror, said first transistor configured to receive an output of said control loop, and said second transistor configured to deliver said image of said first current, said sample-and-hold assembly arranged between the control terminals of the first and second transistors.

According to an embodiment, said control loop comprises a current comparator configured to receive an image of said first current.

According to an embodiment, said second transistor is further configured to receive said reference current.

According to an embodiment, said second reference current is delivered by a digital-to-analog converter.

Another embodiment provides a switched-mode power supply comprising a previously described current sensing circuit.

According to an embodiment, the switched-mode power supply is a buck-type switched-mode power supply, a boost-type switched-mode power supply, or a buck-boost-type switched-mode power supply.

Another embodiment provides a device comprising a previously described switched-mode power supply.

According to an embodiment, the device is a microcontroller.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows a portion of a switched-mode power supply comprising a current sensing circuit;

FIG. 2 shows an embodiment of a current sensing circuit;

FIG. 3 shows graphs illustrating the operation of the embodiment of FIG. 2;

FIG. 4 shows other graphs illustrating the operation of the embodiment of FIG. 2;

FIG. 5 shows in further detail a portion of the embodiment of FIG. 1;

FIG. 6 shows in further detail a portion of the embodiment of FIG. 1;

FIG. 7 shows in further detail a portion of the embodiment of FIG. 2;

FIG. 8 shows in further detail a portion of the embodiment of FIG. 2;

FIG. 9 shows in further detail a portion of the embodiment of FIG. 2;

FIG. 10 shows in further detail a portion of the embodiment of FIG. 2; and

FIG. 11 shows an application of the described embodiments.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

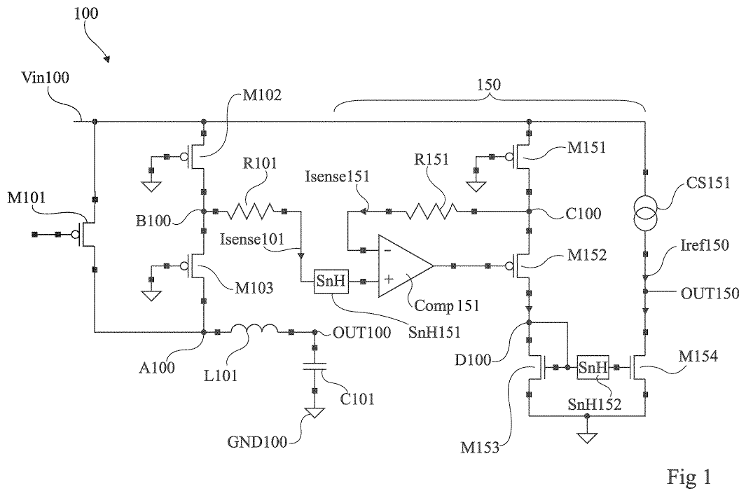

The embodiments described hereafter concern the implementation of a switched-mode power supply, and more particularly the implementation of a sensing of an output current of this switched-mode power supply by a current sensing circuit. The sensing of the exceeding of a threshold current by an output current of a switched-mode power supply may be delayed in certain cases. The present disclosure provides a solution for overcoming this problem by adding a sample-and-hold assembly (SnH) to the current sensing circuit. This is described in relation with FIGS. 1 to 10.

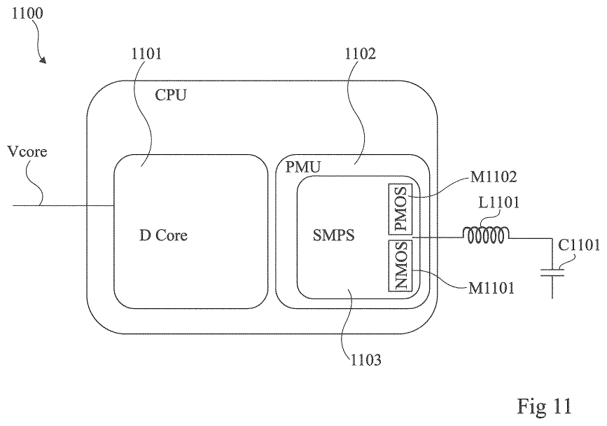

Moreover, the embodiments described hereafter are particularly used in a generic microcontroller for small or large household appliances, electronic cigarettes, computer peripherals, cell phones, etc. An application of these embodiments is described in more detail in relation with FIG. 11.

Further, the embodiments described hereabove are particularly used in any type of industrial market where a switched-mode power supply is required. More particularly, such a switched-mode power supply may be intended for: the automotive industry, for example in the field of automotive electrification or in the field of advanced driver assistance systems (ADAS); the industrial sector, for example in the field of green energy, in the field of infrastructure electrification, of the Internet of Things (IoT), and of smart homes, where electricity and energy consumption and data exchange are key elements; the personal electronics industry, for example in mobile telephony and the Internet of Things (IoT), as well as in high-speed interfaces; and the industry of communications equipment, computers, and peripherals, for example in the field of infrastructure and data centers, and in the field of low earth orbit (LEO) satellites.

A switched-mode power supply (or switching converter) generally comprises two switches, for switching a DC voltage to be converted, in series between two terminals for applying this voltage to be converted. The midpoint between these switches is connected, via an inductive circuit (coil or other), to a terminal supplying a DC voltage, smoothed by a capacitive element between this supply terminal and a voltage reference terminal (for example, the reference terminal of the voltage to be converted). The switch connecting the terminal of application of the higher potential (of the voltage to be converted) to the midpoint connected to the inductive circuit is generally referred to as the high-side switch, and the switch connecting this midpoint to the lower potential (reference terminal) of the voltage to be converted is referred to as the low-side switch. The high-side switch is controlled by a switching signal. The low-side switch can be a controllable switch (with a control terminal) or an automatic switch (diode type). Semiconductor switches are generally power MOS transistors with a P-channel on the high side and an N-channel on the low side. If some converters, the lower switch is a diode (known as a freewheeling diode).

FIG. 1 shows a portion of a switched-mode power supply 100 comprising a current sensing circuit 150 according to an embodiment.

Portion 100 further comprises a high-voltage switch M101, that is, a switch configured to receive, on one of its conduction terminals, a voltage Vin100 to be converted (this terminal being coupled to a first terminal of application of the high potential of this voltage) and to supply a converted voltage to an output of the switched-mode power supply via a coil L101. A second terminal of switch M101 is coupled, preferably connected, to node A100 couple to the coil L101. The control terminal of switch M101 is configured to receive a control voltage from the switched-mode power supply.

Switch M101 is the switch on the high side of the switched-mode power supply. Node A100 is thus coupled, by a switch on the low side (not represented), to the other terminal of application of voltage Vin100.

According to an embodiment, high-voltage switch M101 is a metal-oxide-semiconductor field-effect transistor (MOSFET). Further, switch M101 is a P-channel MOS transistor, or P-type MOS transistor, or PMOS transistor.

Similarly, a switched-mode power supply typically further comprises a low-side switch (not shown in FIG. 1), that is, a switch configured to be coupled node A100 to a second terminal of application of voltage Vin100, for example, a reference voltage GND100, for example, the ground.

The operation of a switched-mode power supply is based on a succession of alternating conduction and non-conduction phases of the high-side switch (on the side of the high potential) and of the low-side switch (on the side of the low potential). This operation is conventional and within the abilities of those skilled in the art.

Portion 100 further comprises two switches M102 and M103 arranged in series with each other and forming an assembly parallel to switch M101. According to an example, switches M102 and M103 are both switches of the same type as switch M101, that is, in the case illustrated in FIG. 1, PMOS-type transistors. Thus, a first conduction terminal of switch M102 is coupled, preferably connected, to the node delivering the voltage Vin100 to be converted, and a second conduction terminal of switch M102 is coupled, preferably connected, to a first conduction terminal of switch M103 and to a node B100. A second conduction terminal of switch M103 is coupled, preferably connected, to node A100. The control terminals of switches M102 and M103 are configured to receive control voltages of the same type as the control voltage received by the control terminal of switch M101.

Node B100 is a node delivering an image current of the output current of the switched-mode power supply, which image of the current is that proposed to be evaluated by current sensing circuit 150.

According to an example, the inductive circuit (coil L101) and a filtering capacitive element form and filtering circuit. Portion 100 then further comprises such an LC-type filtering circuit comprising coil L101 and a capacitor C101. This filtering circuit is arranged between node A100 and a node delivering reference voltage GND100. More particularly, a first terminal of coil L101 is coupled, preferably connected, to node A100, and a second terminal of coil L101 is coupled, preferably connected, to a first terminal of capacitor C101, noted node OUT100. A second terminal of capacitor C101 is coupled, preferably connected, to the node delivering reference voltage GND100. Node OUT100 is the output node of the switched-mode power supply and enables to deliver an output voltage of the switched-mode power supply.

As previously mentioned, portion 100 is equipped with a current sensing circuit 150 configured to sense and to evaluate an output current of the switched-mode power supply, and, more particularly, an image current Isense101 of this output current delivered by node B100.

According to an example, circuit 150 comprises a control loop configured to receive the current Isense101 to be measured. This control loop comprises, for example, a comparator circuit Comp151, two transistors M151 and M152, and a resistor R151. A non-inverting input (+) of comparator circuit Comp151, or comparator Comp151, is configured to receive the current to be measured Isense101, for example, via a resistor R101 of portion 100. An inverting input (−) of comparator circuit Comp151 is coupled, preferably connected, to a first terminal of resistor R151. A second terminal of resistor R151 is coupled, preferably connected, to node C100. Transistors M151 and M152 are, for example, PMOS-type transistors. A first conduction terminal of transistor M151 is coupled, preferably connected, to the node delivering voltage Vin100, and a second conduction terminal of transistor M151 is coupled, preferably connected, to node C100. A control terminal of transistor M151 is configured to receive a control voltage. A first conduction terminal of transistor M152 is coupled, preferably connected, to node C100, and a second conduction terminal of transistor M151 is coupled, preferably connected, to node D100. A control terminal of transistor M152 is coupled, preferably connected, to the output node of comparator circuit Comp151.

According to an example, circuit 150 further comprises a current mirror assembly, also designated as current mirror circuit, or simply current mirror. This assembly comprises two transistors M153 and M154, which are, for example, N-channel MOS transistors, or N-type MOS transistors, or NMOS transistors. A first conduction terminal of transistor M153 is coupled, preferably connected, to node D100, and a second conduction terminal of transistor M153 is coupled, preferably connected, to the node delivering reference voltage GND100. A first conduction terminal of transistor M154 is coupled, preferably connected, to an output node OUT150 of circuit 150, and a second conduction terminal of transistor M154 is coupled, preferably connected, to the node delivering reference voltage GND100. The control terminals of transistors M153 and M154 are coupled to each other and to node D100.

According to an example, circuit 150 further comprises a current source CS151 configured to deliver a current which does not depend on temperature. Current source CS151 is, for example, configured to supply a reference current Iref150 to output node OUT150. According to an example, current source CS151 is powered with voltage Vin100. According to an example, the current source may be partly implemented by a digital-to-analog converter.

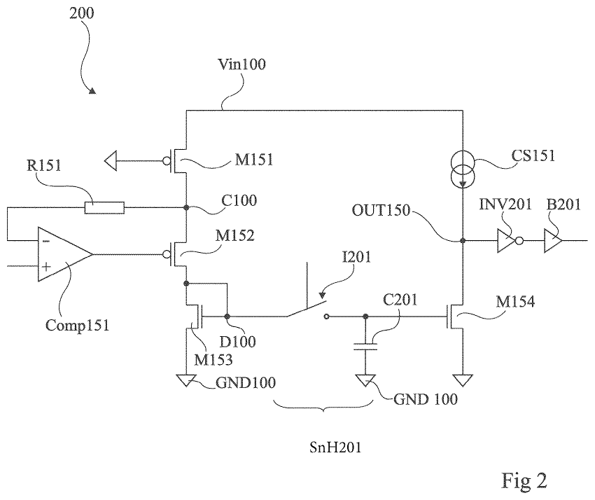

According to an embodiment, circuit 150 further comprises a sample-and-hold (SnH) circuit. This circuit enables to store the value of current Isense101 measured by circuit 150 during a non-conduction phase of switch M101. Indeed, circuit 150 is arranged at the output of switch M101 and can only measure current Isense101 during a conduction phase of switch M101 and of switches M102 and M103. An example of a sample-and-hold circuit is described in detail in relation with FIG. 2. Two possible locations of the sample-and-hold circuit are illustrated in FIG. 1.

According to a first embodiment, illustrated by sample-and-hold circuit SnH151 in FIG. 1, circuit SnH151 is arranged at the input of circuit 150. More specifically, circuit SnH151 is arranged at the input of the control loop, that is, for example, at the input of comparator circuit Comp151. According to an example, an input terminal of circuit SnH151 is coupled, preferably connected, to node B100, or to a connection terminal of resistor R101, and an output terminal of circuit SnH151 is coupled, preferably connected, to the inverting input terminal of comparator circuit Comp151.

According to a second embodiment, illustrated by sample-and-hold circuit SnH152 in FIG. 1, circuit SnH152 is arranged in the current mirror assembly. More particularly, circuit SnH152 is positioned between the control terminals of transistors 153 and M154. According to an example, an input terminal of circuit SnH152 is coupled, preferably connected, to the control terminal of transistor M153, and an output terminal of circuit SnH151 is coupled, preferably connected, to the control terminal of transistor M154.

According to a third embodiment, not shown in FIG. 1, the sample-and-hold circuit may be located upstream of the current mirror circuit, for example being within another current mirror assembly arranged upstream of that formed by transistors M153 and M154.

According to an embodiment, a method of using circuit 150 is the following. The sample-and-hold circuit is enabled to store the value of the current to be measured at the beginning of a non-conduction phase of switch M101. According to an example, the sample-and-hold circuit is enabled by a sampling signal, also known as a control signal. According to an example, the sample-and-hold circuit may not be directly enabled at the beginning of a non-conduction phase, but may allow a delay to let the current stabilize.

In the disclosed embodiments, the current only needs to be measured on the high side of the converter. Circuit 150 therefore does not need to be duplicated on the low side (on the side of the low-side transistor).

Furthermore, the use of a sampling circuit allows a picture of the converter current to be maintained even during periods when the high transistor M101 is open (off). This allows an accurate comparison to be made between the reference current Iref150 and the measured current of the converter (current in transistor M154) without the need for high speed (a response in the microsecond range is sufficient). The comparator can then be of simple construction. Typically, the comparator can consist of two current mirrors, resulting in low power consumption and a small silicon area, which helps to reduce the production costs of the circuit integrating the converter. Without a sampling circuit, a fast comparator (in the order of 100 ns for switching frequencies of several hundred kHz/Mhz) would have been required to obtain a comparison during the periods when the high transistor is on.

FIG. 2 shows a current sensing circuit 200 of the type of the circuit 150 described in relation with FIG. 1. More particularly, FIG. 2 illustrates an example of implementation of the first embodiment described in relation with FIG. 1.

Circuit 200 comprises the same components as circuit 150. In other words, circuit 200 comprises: the control loop comprising comparator circuit Comp151, resistor R151, and transistors M151 and M152; and the current mirror circuit comprising transistors M153 and M154.

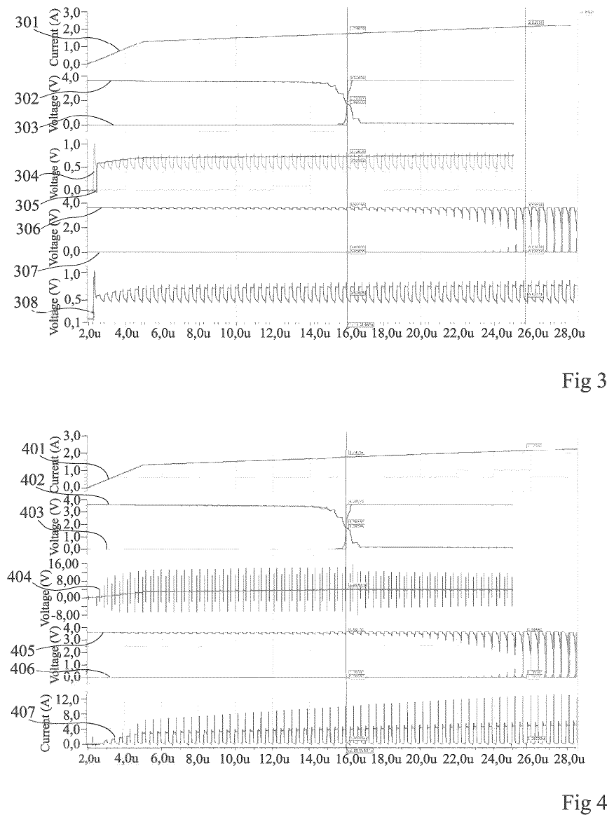

According to an embodiment, circuit 200 further comprises a sample-and-hold circuit SnH201 arranged like the circuit SnH152 described in relation with FIG. 1. According to an embodiment, circuit SnH201 comprises a switch I201 and a capacitor C201. A first conduction terminal of switch I201 is coupled, preferably connected, to the first conduction terminal of transistor M153 and to the control terminal of this same transistor, and a second conduction terminal of switch I201 is coupled, preferably connected, to the control terminal of transistor M154. A control terminal of switch I201 is configured to receive a control voltage. Such a control voltage is detailed in relation with FIGS. 3 and 4. A first terminal of capacitor C201 is coupled, preferably connected, to the control terminal of transistor M154, and a second terminal of capacitor C201 is coupled, preferably connected, to the node delivering reference voltage GND100.

According to an example, circuit 200 further comprises an inverter circuit INV201 and a buffer circuit B201. According to an example, an input terminal of inverter circuit INV201 is coupled, preferably connected, to node OUT150, and an output terminal of inverter circuit INV201 is coupled, preferably connected, to an input terminal of buffer circuit B201. An output terminal of buffer circuit B201 forms an output terminal of circuit 200.

FIGS. 3 and 4 are graphs illustrating the operation of the circuit 200 described in relation with FIG. 2.

FIG. 3 comprises the following graphs: a curve 301 illustrating the variation of an output current of the switched-mode power supply; a curve 302 illustrating the variation of the output voltage of circuit 200 at node OUT150; a curve 303 illustrating the variation of the output voltage of circuit 200 at node OUT150; a curve 303 illustrating the variation of the output voltage of circuit 200 at the output of buffer circuit B201; a curve 304 illustrating the variation of the gate-source voltage of transistor M153, which is an image of the current to be measured; a curve 305 illustrating the variation of the gate-source voltage of transistor M154, which is an image of the current to be measured; a curve 306 illustrating the variation of the output voltage of a circuit of the type of circuit 200, but comprising no sample-and-hold circuit, at node OUT150; a curve 307 illustrating the variation of the output voltage of a circuit of the type of circuit 200 but comprising no sample-and-hold circuit, at the output of buffer circuit B201; and a curve 308 illustrating the variation of the current image at the control terminal of the transistor M154 of a circuit of the type of circuit 200 but comprising no a sample-and-hold circuit.

FIG. 4 comprises the following graphs: a curve 401 illustrating the variation of an output current of the switched-mode power supply; a curve 402 illustrating the variation of the output voltage of circuit 200 at node OUT150; a curve 403 illustrating the variation of the output voltage of circuit 200 at the output of buffer circuit B201; a curve 404 illustrating the variation of the drain-source current of transistor M154; a curve 405 illustrating the variation of the output voltage of a circuit of the type of circuit 200, but comprising no sample-and-hold circuit, at node OUT150; a curve 406 illustrating the variation of the output voltage of a circuit of the type of circuit 200 but comprising no sample-and-hold circuit, at the output of buffer circuit B201; and a curve 407 illustrating the variation of the drain-source current of transistor M154 of a circuit of the type of circuit 200 but comprising no sample-and-hold circuit.

These curves enable to show that the use of a sampler circuit enables rapid detection of the exceeding of a threshold by the output current of the switched-mode power supply.

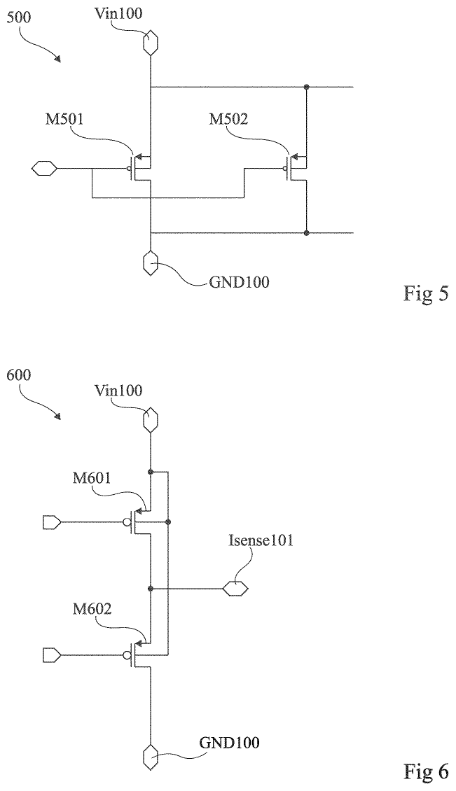

FIG. 5 shows a practical example of embodiment of a portion of the portion 100 described in relation with FIG. 1. More particularly, FIG. 5 illustrates a practical example switch 500 for the switch M101 described in relation with FIG. 1.

According to an example, switch 500 comprises two transistors M501 and M502, for example PMOS-type transistors, arranged in parallel.

More particularly, according to an example, a source terminal of transistor M501 is coupled, preferably connected, to a terminal delivering voltage Vin100, and a drain terminal of transistor M501 is coupled, preferably connected, to a terminal delivering reference voltage GND100. According to an example, a source terminal of transistor M502 is coupled, preferably connected, to a terminal delivering voltage Vin100, and a drain terminal of transistor M502 is coupled, preferably connected, to a terminal delivering reference voltage GND100. The gate terminals of transistors M501 and M5002 are coupled to each other and to a node delivering a control voltage defining the conduction and non-conduction phases of transistors M501 and M502.

FIG. 6 shows a practical example of a portion of the portion 100 described in relation with FIG. 1. More particularly, FIG. 6 illustrates a practical example 600 of the switches M102 and M103 described in relation with FIG. 1.

According to an example, circuit 600 comprises two transistors M601 and M602, for example PMOS transistors, arranged in series.

More particularly, according to an example, a source terminal of transistor M601 is coupled, preferably connected, to a terminal delivering voltage Vin100, and a drain terminal of transistor M601 is coupled, preferably connected, to a source terminal of transistor M602, and delivers current Isense101. According to an example, a drain terminal of transistor M602 is coupled, preferably connected, to the node delivering reference voltage GND100.

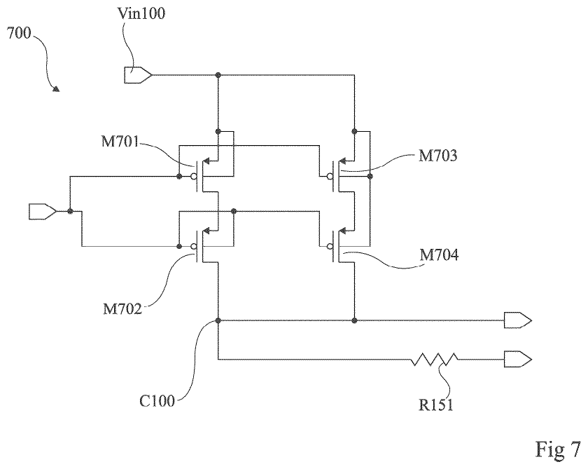

FIG. 7 shows a practical example of a portion of the circuit 150 described in relation with FIG. 1. More particularly, FIG. 7 illustrates a practical example 700 of embodiment of the transistor M151 described in relation with FIG. 1.

According to an example, circuit 700 comprises four bridge-connected transistors M701, M702, M703, and M704, for example PMOS-type transistors. Resistor R151 is also shown in FIG. 7.

More particularly, according to an example, a source terminal of transistor M701 is coupled, preferably connected, to a terminal delivering voltage Vin100, and a drain terminal of transistor M701 is coupled, preferably connected, to a source terminal of transistor M702. According to an example, a drain terminal of transistor M702 is coupled, preferably connected, to node C100 and to a first terminal of resistor R151. According to an example, a source terminal of transistor M703 is coupled, preferably connected, to a terminal delivering voltage Vin100, and a drain terminal of transistor M703 is coupled, preferably connected, to a source terminal of transistor M704. According to an example, a drain terminal of transistor M704 is coupled, preferably connected, to node C100 and to a first terminal of resistor R151. All the gate terminals of transistors M701, M702, M703, and M704 are connected to one another and to a node delivering a control voltage.

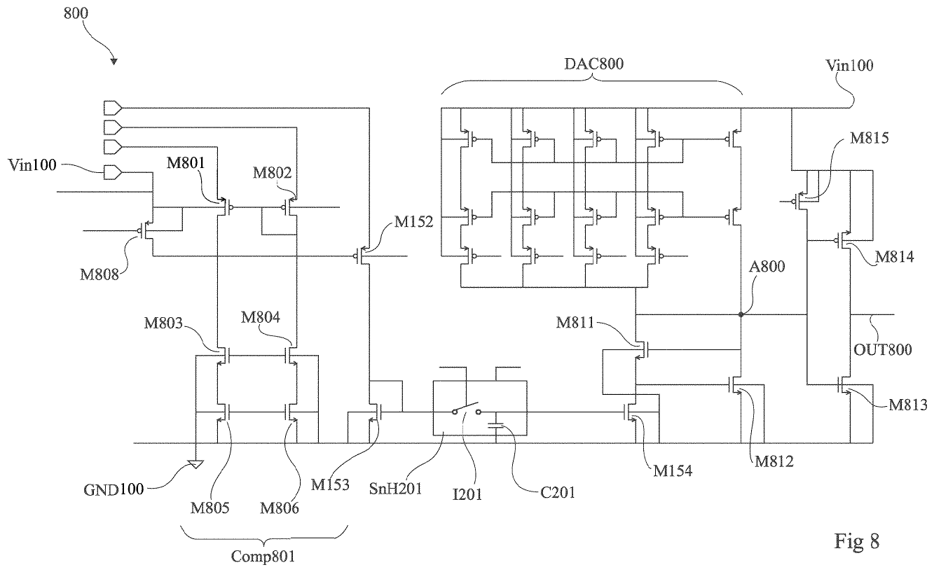

FIG. 8 shows a practical example of embodiment of a portion of the circuit 150 described in relation with FIG. 1. More specifically, FIG. 8 illustrates a practical example 800 of the comparator Comp151, the current mirror circuit, the sample-and-hold circuit SnH152, and the current source CS151 described in relation with FIG. 1.

According to an example, circuit 800 comprises: a comparator Comp801, which is a practical example of comparator Comp151; and a current source.

According to an example, comparator Comp801 comprises seven transistors: M801, M802, M803, M804, M805, M806, and M808. Transistors M801, M802, and M808 are, for example, PMOS-type transistors. Transistors M803 to M807 are, for example, NMOS-type transistors.

Transistors M801 and M802 are connected as a current mirror. According to an example, the source terminal of transistor M801 forms the inverting terminal of comparator Comp801, and the drain terminal of transistor M801 is coupled, preferably connected, to a terminal forming the output terminal of comparator Comp801 and thus is coupled, preferably connected, to the gate terminal of transistor M152. According to an example, the source terminal of transistor M802 forms the non-inverting terminal of comparator Comp801, and the drain terminal of transistor M802 is coupled, preferably connected, to the terminal forming the output terminal of comparator Comp801 and is thus coupled, preferably connected, to the gate terminal of transistor M152. The gate terminals of transistors M801 and M802 are coupled to each other and to the drain terminal of transistor M802.

According to an example, transistors M803, M804, M805, and M806 are bridge-connected. More particularly, according to an example, a drain terminal of transistor M803 is coupled, preferably connected, to the source terminal of transistor M801, and a source terminal of transistor M803 is coupled, preferably connected, to a drain terminal of transistor M805. According to an example, a source terminal of transistor M805 is coupled, preferably connected, to the node delivering reference voltage GND100. According to an example, a drain terminal of transistor M804 is coupled, preferably connected, to the source terminal of transistor M802, and a source terminal of transistor M804 is coupled, preferably connected, to a drain terminal of transistor M806. According to an example, a source terminal of transistor M806 is coupled, preferably connected, to the node delivering reference voltage GND100. According to an example, the gate terminals of transistors M803 and M804 are coupled to each other and to a node delivering a control voltage. Transistors M803 and M804 are cascode-connected to limit the drain voltage of transistors M805 and M806. According to an example, the gate terminals of transistors M805 and M806 are coupled to each other and to a node delivering a control voltage. Transistors M805 and M806 act as a current source and bias the structure formed by circuit 800.

According to an example, a source terminal of transistor M808 is coupled, preferably connected, to a terminal receiving voltage Vin100, and a drain terminal of transistor M808 is coupled, preferably connected, to the drain terminal of transistor M801.

Transistors M153 and M154 are shown in FIG. 8, along with the sample-and-hold circuit NH201 described in relation with FIG. 2.

According to an example, the current source comprises a digital-to-analog converter DAC800 comprising a plurality of PMOS-type transistors arranged in an array according to an assembly known to those skilled in the art. In the example shown, the converter DAC800 has four identical branches (4-bit converter) in parallel between the application node (high node) of voltage Vin100 and the drain (node A800) of a transistor M811, by example of NMOS type, cascode-connected with transistor M154. According to an example, a source terminal of transistor M811 receives a cascode voltage from a transistor M812, for example of NMOS type. According to an example, a source terminal of transistor M812 is coupled, preferably connected, to the node receiving reference voltage GND100. A gate terminal of transistor M812 is coupled, preferably connected, to the source terminal of transistor M811 (drain terminal of transistor M154). Transistor M812 is biased by being coupled to the node of application of the high potential of voltage Vin100 by two PMOS transistors connected as a current mirror on the transistors forming the current sources of the digital to analog converter.

Node A800 provides the result of the digital-to-analog conversion producing the reference current Iref150 from a digital setpoint (in this example, a 4-bit setpoint). This node A800 corresponds, for example, to node OUT150 in FIG. 1.

The comparison between the reference current and the SMPS converter current (of which the current flowing through transistor M154 is an image) is performed by a stage consisting of transistors M813, M814, and M815, which provide digital information on whether the reference current is lower or greater to the converter current at a node OUT800. According to an example, transistor M813 is of NMOS type. According to an example, a source terminal of transistor M813 is coupled, preferably connected, to the node receiving reference voltage GND100, and a drain terminal of transistor M813 is coupled, preferably connected, to an output node OUT800. A gate terminal of transistor M813 is coupled, preferably connected, to node A800.

According to an example, transistor M814 is of PMOS type. According to an example, a source terminal of transistor M814 is coupled, preferably connected, to the node delivering voltage Vin100 (high potential), and a drain terminal of transistor M814 is coupled, preferably connected, to output node OUT800. A gate terminal of transistor M814 is coupled, preferably connected, to node A800.

According to an example, transistor M815 is of PMOS type. According to an example, a source terminal of transistor M815 is coupled, preferably connected, to the node delivering voltage Vin100, and a drain terminal of transistor M814 is coupled, preferably connected, to node A800. Transistor M815 enables to avoid for node A800 to be floating when circuit 800 is off.

The use of a digital-to-analog converter facilitates adjustment of the reference current and thus of the detection threshold.

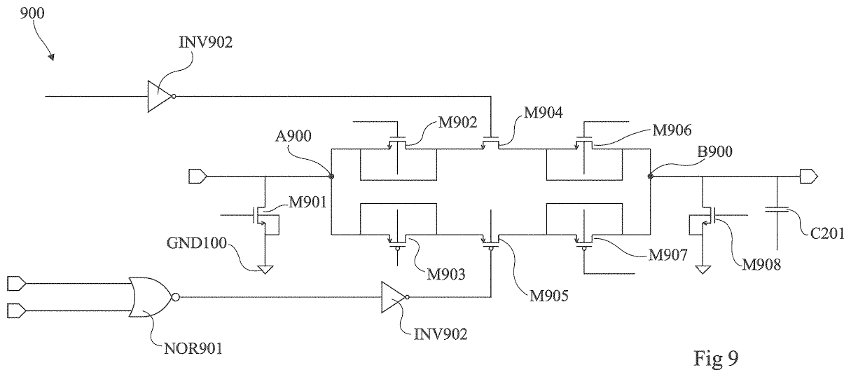

FIG. 9 shows a practical example of embodiment of a portion of the circuit 200 described in relation with FIG. 2. More particularly, FIG. 9 illustrates a practical example 900 of embodiment of the switch I201 described in relation with FIG. 2.

According to an example, circuit 900 comprises bridge-connected transistors M901, M902, M903, M904, M905, M906, M907, and M908, two inverters, and a NOR-type logic gate. Resistor R151 is also shown in FIG. 7. Transistors M901, M902, M904, M906, and LM908 are of NMOS type. Transistors M903, M905, and LM907 are of PMOS type.

According to an example, a drain terminal of transistor M901 is coupled, preferably connected, to an input terminal of circuit 900, noted A900, and a source terminal of transistor M901 is coupled, preferably connected, to the node receiving reference voltage GND100.

According to an example, a source terminal of transistor M902 is coupled, preferably connected, to its drain terminal and to node A900. A gate terminal of transistor M902 receives a control voltage. According to an example, a source terminal of transistor M904 is coupled, preferably connected, to its drain terminal. A gate terminal of transistor M904 receives a control voltage. According to an example, a source terminal of transistor M906 is coupled, preferably connected, to its drain terminal and to the output terminal of circuit 900 noted node B900. A gate terminal of transistor M906 receives a control voltage.

According to an example, a source terminal of transistor M903 is coupled, preferably connected, to its drain terminal and to node A900. A gate terminal of transistor M903 receives a control voltage. According to an example, a source terminal of transistor M905 is coupled, preferably connected, to its drain terminal. A gate terminal of transistor M905 receives a control voltage. According to an example, a source terminal of transistor M907 is coupled, preferably connected, to its drain terminal and to the output terminal of circuit 900 noted node B900. A gate terminal of transistor M907 receives a control voltage.

According to an example, a drain terminal of transistor M908 is coupled, preferably connected, to node B900, and a source terminal of transistor M908 is coupled, preferably connected, to the node receiving reference voltage GND100.

An input terminal of inverter INV902 receives a control voltage and an output terminal of inverter INV902 is coupled, preferably connected, to the gate terminal of transistor M904.

The input terminals of gate NOR901 receive control voltages. The output terminal of gate NOR901 is coupled, preferably connected, to the input of inverter INV902. An output terminal of inverter INV902 is coupled, preferably connected, to the gate terminal of transistor M905.

FIG. 9 further shows capacitor C201.

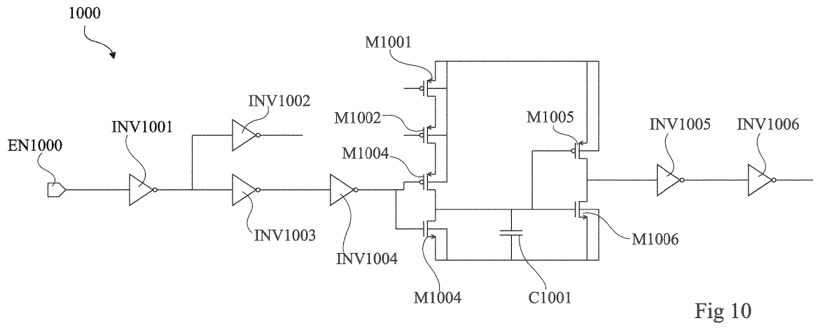

FIG. 10 shows an example of a delay circuit 1000 capable of applying a delay for the enabling of the sample-and-hold circuit.

Such a circuit enables to give the current to be measured time to stabilize before its value is stored in the sample-and-hold circuit.

According to an example, circuit 1000 comprises a plurality of inverter circuits INV1001, INV1002, INV1003, INV1004, INV1005, INV1006, transistors M1001, M1002, M1003, M1004, M1005, M1006, and a capacitor C1001. Transistors M1001, M1002, M1003, and M1005 are of PMOS type, while transistors M1004 and M1006 are of NMOS type.

According to an example, an input terminal of inverter INV1001 is coupled, preferably connected, to a node delivering an enable signal EN1000. An output terminal of the inverter INV1001 is connected to an input terminal of the inverter INV1002 and to an input terminal of inverter INV1003. An output terminal of inverter INV1002 is coupled, preferably connected, to a node delivering an enable signal. An output terminal of inverter INV1003 is coupled, preferably connected, to a gate terminal of transistor M1003 and to a gate terminal of transistor M1004.

According to an example, a source terminal of transistor M1001 is coupled, preferably connected, to a node delivering a power supply voltage, and a drain terminal of transistor M1001 is coupled, preferably connected, to a source terminal of transistor M1002. A drain terminal of transistor M1002 is coupled, preferably connected, to a source terminal of transistor M1003. A drain terminal of transistor M1003 is coupled, preferably connected, to a drain terminal of transistor M1004. A drain terminal of transistor M1004 is coupled, preferably connected, to a node delivering a reference voltage.

According to an example, a first terminal of capacitor C1001 is coupled, preferably connected, to the junction point of transistors M1003 and M1004. A second terminal of capacitor C1001 is coupled, preferably connected, to the node receiving the reference voltage.

According to an example, a source terminal of transistor M1005 is coupled, preferably connected, to the node delivering the power supply voltage, and a drain terminal of transistor M1005 is coupled, preferably connected, to the drain terminal of transistor M1006. The source terminal of transistor M1006 is coupled, preferably connected, to the node receiving the reference voltage. The gate terminals of transistors M1005 and M1006 are coupled, preferably connected, to each other and to the junction point of transistors M1003 and M1004.

According to an example, an input terminal of the INV1005 inverter is coupled, preferably connected, to the junction point of transistors M1005 and M1006. An output terminal of inverter INV1005 is coupled to an input terminal of inverter INV1006. An output terminal of inverter INV1006 is configured to deliver a delayed signal.

FIG. 11 very schematically shows in the form of blocks an electronic device 1100 (CPU).

According to an example, electronic device 1100 is a controller, a microcontroller, a processor, or a microprocessor.

This device 1100 comprises, for example, a digital core 1101 (D. Core) configured to receive an input voltage Vcore.

This device 1100 comprises, for example, a power management unit 1102 (PMU) comprising a switched-mode power supply 1103. Switched-mode power supply 1103 comprises high and low transistors M1101 (NMOS) and M1102 (PMOS). Switched-mode power supply 1103 comprises a current sensing circuit according to an embodiment. Device 1100 may complement the switched-mode power supply with an external coil L1101 and an external capacitor C1101. According to an example, the switched-mode power supply is a buck-type power supply, a boost-type switched-mode power supply, or a buck-boost-type switched-mode power supply.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A circuit for sensing a first output current of a switched-mode power supply, comprising:
a sample-and-hold assembly configured to store an image of said first output current during a non-conduction phase of a high-voltage switch of said switched-mode power supply.

2. The circuit according to claim 1, wherein said sample-and-hold assembly comprises a switch and a capacitor.

3. The circuit according to claim 1, wherein said image is an image of the current flowing in said high-voltage switch.

4. The circuit according to claim 1, wherein a result provided by said sample-and-hold assembly is compared to a threshold, in order to provide an information about a threshold exceeding.

5. The circuit according to claim 1, wherein said threshold is provided by a reference current provided by a digital to analog converter.

6. The circuit according to claim 1, wherein said sample-and-hold circuit is controlled by a sampling signal.

7. The circuit according to claim 6, wherein said sampling signal triggers storage of said image of said first current with a time delay.

8. The circuit according to claim 1, wherein said sample-and-hold assembly is configured to directly receive said first current, and further comprising a control loop having an input coupled to an output of the sample-and-hold assembly.

9. The circuit according to claim 1, further comprising:
a control loop configured to receive a first current to be sensed; and
a first transistor and a second transistor connected as a current mirror, said first transistor being configured to receive an output of said control loop, and said second transistor being configured to deliver said image of said first current;
wherein said sample-and-hold assembly is arranged between control terminals of the first and second transistors.

10. The circuit according to claim 9, wherein said control loop comprises a current comparator configured to receive said first current.

11. The circuit according to claim 9, wherein said second transistor is configured to further receive a second reference current.

12. The circuit according to claim 11, wherein said second reference current is delivered by a digital-to-analog converter.

13. A switched-mode power supply, comprising the circuit for sensing according to claim 1.

14. The power supply according to claim 13, configured as one of a buck-type switched-mode power supply, a boost-type switched-mode power supply, or a buck-boost-type switched-mode power supply.

15. A device, comprising the switched-mode power supply according to claim 13.

16. The device according to claim 15, configured as a microcontroller.
